(19) United States
(12) Patent Application Publication
(10) Pub. No.: US 2010/0062266 A1
(43) Pub. Date: Mar. 11, 2010

(54) Method for growing epitaxy

(75) Inventor: Chien-Min Sung, Danshuei Township (TW)

Correspondence Address: BACON & THOMAS, PLLC, 625 SLATERS LANE, FOURTH FLOOR, ALEXANDRIA, VA, 22314-1176, US

(73) Assignee: Chien-Min Sung, Danshuei Township (TW)

(21) Appl. No.: 12/320,228

(22) Filed: Jan. 22, 2009

(30) Foreign Application Priority Data
Sep. 8, 2008 (TW) 097134370

(51) Int. Cl. C30B 19/04; B32B 13/04

(52) U.S. Cl. 428/446; 117/81; 428/704

(57) ABSTRACT

A method for growing epitaxy is disclosed, which includes providing a mold; providing a substrate which is disposed in the mold; providing a solvent and a solute, and liquefying the solvent to allow the solute melted therein so as to form a melting solution between the substrate and the mold; and forming a first epitaxial layer on the substrate, wherein the first epitaxy is formed on the substrate by a temperature gradient of the melting solution melting the mold and the substrate.

### BACKGROUND OF THE INVENTION

1. Field of the Invention

The present invention relates to a method for growing epitaxy and, more particularly, to a method for growing epitaxy in liquid.

2. Description of Related Art

Vapor deposition for forming homo-epitaxy or hetero-epitaxy has been widely applied in material science, especially in the semiconductor industry. For example, posterior to decomposition of silane (SiH₄) at a high temperature by chemical vapor deposition, homo-epitaxy can be grown on a silicon wafer. Alternatively, after graphite has been deposited at a high temperature by decomposition of methane (CH₄), it is catalyzed by any amount of hydrogen to form diamond coated on a substrate. Nevertheless, the deposition rate of the epitaxy grown by vapor deposition is slow, and the lattice in the epitaxy still has many defects. Hence, the manufacture is relatively expensive.

Recently, a technique for growing epitaxy in liquid has been gradually developed. For example, US2004092053 discloses a method for growing epitaxy, in which a compound is solved in a saturated solution containing stibium (Sb) and indium (In) used as solvents to form a transparent layer on an LED substrate. In addition, JP2000234000, JP10001392, JP11003864 and JP2005142270 disclose controlling the epitaxy growth by temperature and a supersaturated solution. US2006175620 discloses controlling unidirectional deposition of epitaxy growth by grooves.

In the conventional method for growing epitaxy in liquid, the epitaxy growth is controlled by the supersaturated solution and grooves. However, it is difficult to control the concentration of the saturated solution so that the nucleation of epitaxy formation is excessively fast and lattice defects occur in the epitaxy. Hence, components with the epitaxial layer made by the conventional method of epitaxy growth have poor performance.

In view of the above, how to provide a method for efficiently controlling epitaxy growth and avoiding lattice detects of the epitaxy owing to chemical composition change during epitaxial deposition is an important issue.

### SUMMARY OF THE INVENTION

The object of the present invention is to provide a method for growing epitaxy so as to promote the growth rate of epitaxy and to decrease the amount of lattice defects inside the epitaxy.

To achieve the object, the method of the present invention includes providing a mold; providing a substrate disposed in the mold; providing a solvent and a solute, and liquefying the solvent to allow the solute dissolving therein to form a melting solution between the substrate and the mold; and forming a first epitaxial layer on the substrate by a temperature gradient of the melting solution melting the mold and the substrate.

According to the method described in a preferred embodiment of the present invention, a heating device is provided on a side of the mold to form a temperature gradient thereby. The temperature gradient is of the temperature reducing gradually from the mold to the substrate. According to the method described in a preferred embodiment of the present invention, a cooling device can be further arranged on the side of the substrate to enlarge the temperature difference between the substrate and the mold.

According to a preferred embodiment of the present invention, the method further includes controlling the concentration of the mold and the substrate melted in the melting solution, and the deposition rate of the first epitaxial layer by regulating the temperature gradient or by ultrasonication. If there are defects in the epitaxial layer, the defects in the epitaxial layer can be melted by the temperature gradient. During the melt of the defects in the epitaxial layer, the substrate and the mold are melted simultaneously and then the first epitaxial layer is reformed on the substrate.

According to the method described in a preferred embodiment of the present invention, the temperature gradient can be regulated during the epitaxy growth to control the growth rate of the epitaxy. The process between the melt of the substrate and the mold to form the solute of epitaxy and the deposition of the epitaxial layer is reversible. Besides, the present invention can simultaneously shake the substrate and the mold by means of a shaking device to increase the uniformity of the melting solution thereby forming the epitaxy having a preferred crystal form on the substrate.

According to the method described in a preferred embodiment of the present invention, the first epitaxial layer formed on the substrate comprises silicon carbide or aluminum nitride, and a diamond layer is formed on the first epitaxial layer.

According to the method described in a preferred embodiment of the present invention, the substrate comprises semiconductor, ceramic (such as sapphire), silicon or aluminum oxide material.

According to the method described in a preferred embodiment of the present invention, the mold is a carbon-containing material, a sintered aluminum nitride or boron nitride. The carbon-containing material is graphite.

According to the method described in a preferred embodiment of the present invention, the solvent and the solute are rare earth elements and transition metal elements, including lanthanum, cerium, iron, cobalt, nickel or the alloy thereof.

According to the method described in a preferred embodiment of the present invention, the melting solution formed by liquefying the solvent to allow the solute to dissolve therein comprises lithium, sodium, calcium, magnesium, nitrogen, boron, aluminum or the alloy thereof.

According to the method described in a preferred embodiment of the present invention, the solvent and the solute are formed on the substrate under vacuum or under atmosphere of inert gas (such as nitrogen).

According to a preferred embodiment of the present invention, the method further includes forming as metal nitride layer on the first epitaxial layer, and the melting solution comprises lanthanum, cerium, iron, cobalt, nickel or the alloy thereof wherein a second epitaxial layer is formed on the first epitaxial layer by the melting solution melting the first epitaxial layer and the mold. The second epitaxial layer is silicon carbide.

In the method of growing epitaxy described in the present invention, the mold and the substrate are simultaneously melted by the melting solution to form the epitaxial layer. In addition, the growth rate of the epitaxy is controlled by the regulation of the temperature gradient between the substrate and the mold. During the epitaxy growth, the rates between the melt and the deposition are approximately equilibratory, thereby keeping the lattice of the epitaxy stable. Hence, the growth rate of the epitaxy can be efficiently promoted, and the lattice defects inside the epitaxy can be decreased. If the lattice defects occur during the epitaxy growth, the epitaxy can be reformed by melting the epitaxial layer, the mold and the substrate once again. As a result, the defects in the lattice can be reduced efficiently.

Other objects, advantages, and novel features of the invention will become more apparent from the following detailed description when taken in conjunction with the accompanying drawings.

### BRIEF DESCRIPTION OF THE DRAWINGS

FIGS. 1 to 3 show a flowchart of the method for growing epitaxy in the present invention.

### DETAILED DESCRIPTION OF THE PREFERRED EMBODIMENT

### EXAMPLE 1

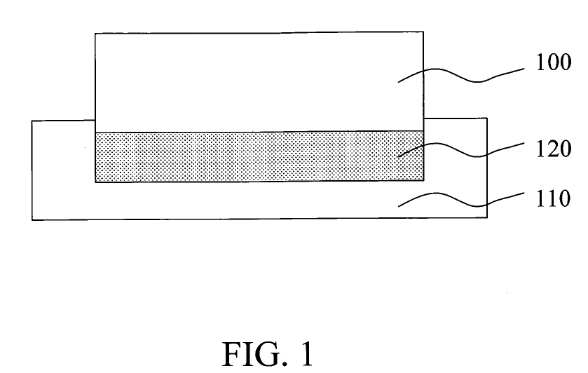

FIGS. 1 to 3 show a flowchart of the method for growing epitaxy in the present invention. First, with reference to FIG. 1, the method for growing epitaxy in the present invention includes providing a substrate 100 and a mold 110. The mold 110 has a receiving space S, and the substrate 100 is disposed in the receiving space S of the mold 110. The mold 110 is made of a carbon-containing material, such as graphite. In the present example, the mold 110 is made of high-pure graphite containing extremely small amounts of non-graphite carbon such as super-pure graphite powder purchased from Morgan Crucible. The substrate 100 is a semiconductor substrate such as a silicon wafer. In the present example, a solute and a solvent are provided, and the solvent is liquefied to allow the solute dissolving therein to form a melting solution 120 between the substrate and the mold. The solute and the solvent can include a metal or an alloy containing two or more metals, and their materials comprise rare earth elements and transition metal elements, for example lanthanum (La), cerium (Ce) or the alloy thereof, and iron, cobalt, nickel or the alloy thereof. Particularly, in the present example, lanthanum or cerium alloy is formed on the substrate 100 by sputtering in vacuum, followed by forming iron, cobalt, nickel or the alloy thereof by sputtering to prevent the lanthanum or cerium alloy from oxidation.

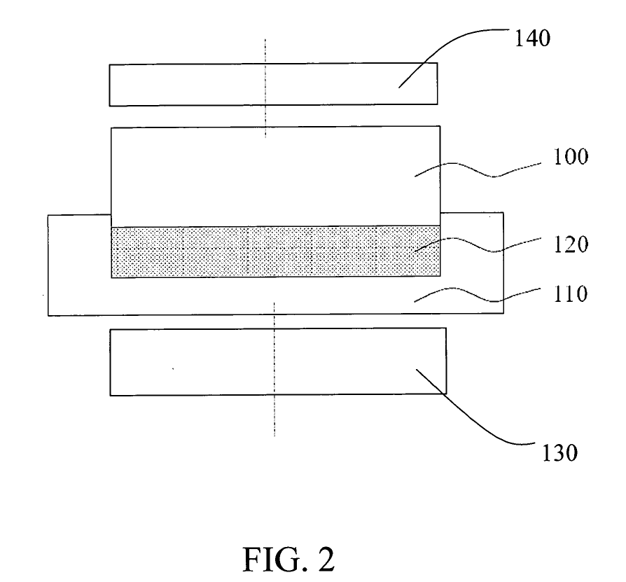

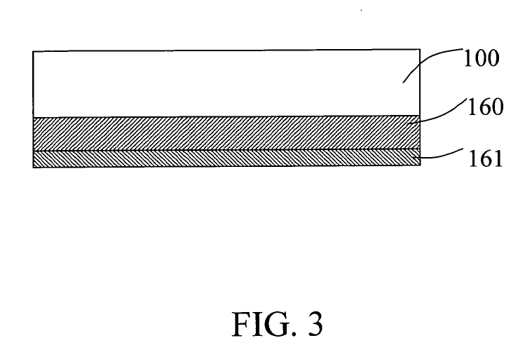

Subsequently, with reference to FIG. 2, a heating device 130 is arranged on a side of the mold 110 to generate temperature variation between the substrate 100 and the mold 110, thereby forming a temperature gradient therebetween. A cooling device 140 can be arranged on the side of the substrate 100 to enlarge the temperature difference between the substrate 100 and the mold 110. Due to the heating device 130, the solute and the solvent are easily melted on the substrate 100, and further form a melting solution 120 between the substrate 100 and the mold 110. Owing to the density of the substrate 100 being lower than the melting solution 120, the substrate 100 floats on the surface of the melting solution 120. The substrate 100 and the mold 110 are melted by the melting solution 120 simultaneously during heating, and the side of the mold 110 is of the melting level greater than that of the substrate 100. Therefore, carbon atoms of the mold 110 diffuse towards the substrate 100, and silicon atoms of the substrate 100 diffuse towards the mold 110. Finally, a first epitaxial layer 160 is formed on the substrate 100 as shown in FIG. 3, and the first epitaxial layer 160 is silicon carbide. In general, if the bonds of silicon carbide are formed with sufficient heating at an optimal temperature, the substitution between carbon and silicon is undergone slowly and thus the ratio of carbon/silicon reduces as the carbon concentration increases in the melting solution. In the present invention, the temperature gradient can be regulated to control the reduction rate of the silicon/carbon ratio during the growth of the first epitaxial layer. Therefore, the ratio of silicon/carbon varies slowly in accordance with the variation of the temperature gradient. As a result, the first epitaxial layer 160 can be gradually formed on the substrate 100 so as to prevent defects being formed therein.

In the present example, the temperature gradient can be regulated during the epitaxy growth, and in other words, the concentration of the mold 110 melted in the melting solution 120 can be adjusted to control the growth rate of the first epitaxial layer 160. Besides, if there are lattice defects in the deposited first epitaxial layer 160, the first epitaxial layer 160 with the lattice defects, owing to their thermodynamic instability relative to the environment, will be remelted and then deposited once again by the controllable temperature gradient. The process between the melt of the substrate 100 and the mold 110 and the deposition of the first epitaxial layer 160 is reversible.

Besides, in the condition for growing epitaxy, the liquid components need to satisfy the requirements of being liquefied at low temperature and melting carbon atoms of the mold 110 and silicon atoms of the substrate 100. Hence, the liquid temperature should not be higher than the temperature dramatically vaporing the substrate 100. For example, if the substrate is a silicon-containing semiconductor substrate, the liquid temperature should be lower than about 1300° C. to reduce the interference to the lattice integrality. To satisfy these requirements, a eutectic alloy of rare earth elements (such as lanthanum, cerium, or the combination thereof) and transition metal elements (such as iron, cobalt, nickel, or the combination thereof), which has a melting point approximately lower than 600° C., is chosen. If the ratio of silicon/carbon (Si/C) reduces continuously, for example when the deposition rate is lower than 100 nm, the deposited carbon atoms form tetrahedron bonds by the induction of the substrate 100. Hence, a diamond layer (not shown in the figures) can be formed on the first epitaxial layer 160.

### EXAMPLE 2

The method for growing epitaxy in the present example is similar to that of Example 1 except for the following. The substrate 100 used in the present example is a ceramic substrate, for example a sapphire substrate. The mold 110 is made of sintered aluminum nitride. In the present invention, the solvent can be non-metal material such as Mg₃N₂—Ca₃N₂ and be used to dissolve the mold 110 and the substrate 100. Therefore, the melting solution 120 is a eutectic alloy containing lithium, sodium, calcium, magnesium, or nitrogen, and boron, aluminum, calcium, nitrogen, or the compound thereof, for example Mg₃N₂—AlN. The eutectic alloy, Mg₃N₂—AlN, is melted in an atmosphere of inert gas by heating at the temperature higher than 1300° C. to form the melting solution 120 between the substrate 100 and the mold 110. The inert gas is exemplified as nitrogen. If the bottom of the melting solution 120 has a relatively high temperature, aluminum nitride (AlN) diffuses towards the cooler ceramic substrate. Similar to Example 1, the temperature gradient of the melting solution is controlled and vibration is applied to regulate the lattice of the first epitaxial layer 160 (made of aluminum nitride) deposited on the substrate 100, and to reduce the density of the lattice defects.

### EXAMPLE 3

With reference to FIGS. 1 to 3, the method for growing epitaxy in the present example is similar to that of Example 2 except for the following. In the present example, a hetero-epitaxial layer is formed. The mold 110 is made of hexagonal boron nitride (HBN), and a metal nitride layer (not shown in the figures), made of aluminum nitride, is coated on the ceramic substrate 100. The melting solution 120 between the substrate 100 and the mold 110 is the same as that in Example 1. The melting solution 120 can simultaneously melt aluminum nitride, silicon, carbon, or silicon carbide. Due to similar lattices of silicon carbide and aluminum nitride and the small difference (<5%) of the interatomic distances, a second epitaxial layer 161, made of silicon carbide, can be formed on an epitaxial layer made of aluminum nitride when the epitaxial layer made of aluminum nitride is first formed on the substrate 100. Particularly, the melting solution 120 forms by heating in vacuum until being totally melted. Besides, as described in the above-mentioned examples, the temperature gradient between the substrate 100 and the mold 110 is controlled. Meanwhile, the mold 110 and the epitaxial layer made of aluminum nitride are melted in the melting solution 120. In detail, the solutes, carbon and silicon, are melted into the melting solution and diffuse towards aluminum nitride interface. Under the exchange of the solutes, the mixed crystal containing aluminum nitride and silicon carbide is formed, and then the second epitaxial layer 161 made of silicon carbide is formed by transition of the mixed crystal. In fact, the second epitaxial layer 161 attaches on the ceramic substrate 100 by the lattice of aluminum nitride.

In conclusion, the method for growing epitaxy in the present invention is to provide the temperature gradient between the mold and the substrate. Then, the epitaxial layer is formed on the substrate by the melting solution simultaneously melting the mold and the substrate. Hence, the present invention can efficiently promote the growth rate of the epitaxy by reversibility between the deposition of the epitaxial layer and the melt of the substrate and the mold therefor so as to reduce the defect density inside the epitaxial lattice.

Although the present invention has been explained in relation to its preferred embodiment, it is to be understood that many other possible modifications and variations can be made without departing from the scope of the invention as hereinafter claimed.

What is claimed is:

1. A method for growing epitaxy comprising:
providing a mold;
providing a substrate disposed in the mold;
providing a solvent and a solute, and liquefying the solvent to allow the solute dissolving therein to form a melting solution between the substrate and the mold; and
forming a first epitaxial layer on the substrate by a temperature gradient of the melting solution melting the mold and the substrate.

2. The method as claimed in claim 1, further comprising controlling the concentration of the mold and the substrate melted in the melting solution, and the deposition rate of the first epitaxial layer by regulating the temperature gradient or by ultrasonication.

3. The method as claimed in claim 2, wherein the temperature gradient is of the temperature reducing gradually from the mold to the substrate.

4. The method as claimed in claim 1, wherein the process between the melt of the substrate and the mold and the deposition of the first epitaxial layer is reversible, and therefore when the first epitaxial layer has defects, the first epitaxial layer is reformed on the substrate by simultaneously melting the substrate and the mold.

5. The method as claimed in claim 1, wherein when the solvent is liquefied to allow the solute dissolving therein, the substrate and the mold are shaken by a shaking device.

6. The method as claimed in claim 1, wherein the first epitaxial layer formed on the substrate comprises silicon carbide or aluminum nitride.

7. The method as claimed in claim 6, wherein a diamond layer is formed on the first epitaxial layer.

8. The method as claimed in claim 1, wherein the substrate comprises silicon, sapphire or aluminum oxide.

9. The method as claimed in claim 1, wherein the mold is a graphite of carbon-containing material, a sintered aluminum nitride or boron nitride.

10. The method as claimed in claim 1, wherein the solvent and the solute comprise rare earth elements and transition metal elements.

11. The method as claimed in claim 10, wherein the solvent and the solute comprise lanthanum, cerium, iron, cobalt, nickel or the alloy thereof.

12. The method as claimed in claim 10, wherein the melting solution formed by liquefying the solvent to allow the solute dissolving therein comprises lanthanum, cerium, iron, cobalt, nickel or the alloy thereof.

13. The method as claimed in claim 1, wherein the solvent and the solute are formed on the substrate under vacuum or under inert gas atmosphere comprising nitrogen.

14. The method as claimed in claim 6, further comprising forming as metal nitride layer on the first epitaxial layer.

15. The method as claimed in claim 14, wherein the melting solution formed from the melted metal nitride layer comprises lanthanum, cerium, iron, cobalt, nickel or the alloy thereof.

16. The method as claimed in claim 15, wherein a second epitaxial layer is formed on the first epitaxial layer by the melting solution melting the first epitaxial layer and the mold.

17. The method as claimed in claim 16, wherein the second epitaxial layer is silicon carbide.

18. A epitaxial substrate, which is formed by providing a mold, a substrate disposed in the mold, a solvent and a solute; liquefying the solvent to allow the solute dissolving therein to form a melting solution between the substrate and the mold; and forming an epitaxial layer on the substrate by the melting solution melting the substrate and mold.

19. The epitaxial substrate as claimed in claim 18, wherein the substrate is a semiconductor substrate or a ceramic substrate.

20. The epitaxial substrate as claimed in claim 19, wherein the substrate is silicon, sapphire or aluminum oxide.

21. The epitaxial substrate as claimed in claim 18, wherein the epitaxy of the epitaxial layer is aluminum nitride, boron nitride, silicon carbide, or diamond.

22. The epitaxial substrate as claimed in claim 18, wherein the epitaxy of the epitaxial layer comprises homo-epitaxy or hetero-epitaxy.

23. The epitaxial substrate as claimed in claim 18, wherein the solvent and the solute comprise rare earth elements and transition metal elements.

24. The epitaxial substrate as claimed in claim 23, wherein the solvent and the solute comprise lanthanum, cerium, iron, cobalt, nickel or the alloy thereof.
